(19) United States
(12) Patent Application Publication
(10) Pub. No.: US 2021/0262502 A1
(43) Pub. Date: Aug. 26, 2021

(54) MOVABLE HANDLE FIXING STRUCTURE

(71) Applicant: FIVETECH TECHNOLOGY INC., New Taipei City (TW)

(72) Inventors: TING-JUI WANG, New Taipei City (TW); ZI-RONG LIU, New Taipei City (TW)

(21) Appl. No.: 17/182,179

(22) Filed: Feb. 22, 2021

(30) Foreign Application Priority Data
Feb. 26, 2020 (TW) 109106244
Mar. 31, 2020 (TW) 109110976

(51) Int. Cl. F16B 5/06

(52) U.S. Cl. CPC F16B 5/06; H01R 13/62988

(57) ABSTRACT

A movably handle fixing structure including a base and a handle is introduced. The base includes a connecting portion for being coupled to a first object; and the handle is movably coupled to the base and has an operating portion, a fastening portion and an abutting portion. The operating portion is configured on one end of the handle, the fastening portion is configured on the other end of the handle, the abutting portion extends at a bottom of the other end of the handle, and the abutting portion is corresponding to the fastening portion. The abutting portion is pushed by a second object such that the fastening portion is driven to be fastened to the second object; or the fastening portion and the abutting portion are driven by the operating portion to move such that the second object is unfastened.

### CROSS-REFERENCE TO RELATED APPLICATION

This non-provisional application claims priority under 35 U.S.C. § 119(a) on Patent Application No. 109106244 filed in Taiwan, R.O.C. on Feb. 26, 2020, and patent application Ser. No. 10/911,0976 filed in Taiwan, R.O.C. on Mar. 31, 2020, the entire contents of which are hereby incorporated by reference.

### BACKGROUND OF THE INVENTION

### 1. Field of the Invention

The present disclosure relates to a handle, and in particular to a movable handle fixing structure for fastening and unfastening at least two objects and achieving repeated and rapid fastening and unfastening.

### 2. Description of the Related Art

Generally, a screw is used for fixing and coupling objects.

However, in the conventional methods for coupling objects, although at least one object can be fixed and coupled, there is a situation that the object is not easily detached after the coupling.

### BRIEF SUMMARY OF THE INVENTION

In light of the above drawbacks in the conventional methods, the present disclosure provides a movable handle fixing structure for fastening and unfastening at least two objects and achieving repeated and rapid fastening and unfastening.

In other to achieve the above and other purposes, the present disclosure provides a movable handle fixing structure, comprising: a base and a handle. The base has a connecting portion for being coupled with a first object; and the handle is movably assembled with the base and has an operating portion and a fastening portion.

The present disclosure further provides a movable handle fixing structure, comprising: a base and a handle. The base has a connecting portion for being coupled with a first object; and the handle is movably assembled with the base and has an operating portion and an abutting portion.

The present disclosure further provides a movable handle fixing structure, comprising: a base and a handle. The base has a connecting portion for being coupled with a first object; and the handle is movably assembled with the base and has an abutting portion and a fastening portion.

The present disclosure further provides a movable handle fixing structure, comprising: a base and a handle. The base has a connecting portion for being coupled with a first object; and the handle is movably assembled with the base and has an operating portion, a fastening portion and an abutting portion.

In the above movable handle fixing structure, the handle is movably assembled with the base through a shaft.

In the above movable handle fixing structure, the base is formed with a plurality of plates which are corresponding to each other, the connecting portion is disposed at a bottom of the plates, a receiving region is formed among the plates, and the handle is movably disposed in the receiving region.

In the above movable handle fixing structure, the base is formed with a plurality of plates which are corresponding to each other, the handle is disposed in the receiving region, and a shaft is disposed to pass through the plates such that the handle and the base are movably assembled.

In the above movable handle fixing structure, the handle includes at least one first positioning portion or a second positioning portion, the first positioning portion and the second positioning portion are disposed at different positions, the base includes at least one corresponding portion, and the first positioning portion and the second positioning portion are respectively positioned at the corresponding portion.

The handle includes at least one first positioning portion and a second positioning portion, the first positioning portion and the second positioning portion are disposed at different positions, the base includes at least one corresponding portion, and the first positioning portion and the second positioning portion are respectively positioned at the corresponding portion.

In the above movable handle fixing structure, at least one first blocking portion and at least one second blocking portion are formed on at least one surface of the handle, the first blocking portion and the second blocking portion are disposed at different positions, and the first blocking portion and the second blocking portion respectively block against a top surface of the base.

In the above movable handle fixing structure, at least one first blocking portion or at least one second blocking portion is formed on at least one surface of the handle, the first blocking portion and the second blocking portion are disposed at different positions, and the first blocking portion and the second blocking portion respectively block against a top surface of the base.

In the above movable handle fixing structure, a positioning slot is formed on a top surface of the abutting portion for positioning the second object in the positioning slot.

In the above movable handle fixing structure, a positioning slot is formed on a top surface of the abutting portion, wherein the positioning slot is used as a moving track for the second object to move therein.

In the above movable handle fixing structure, the connecting portion has a positioning column, and the positioning column is used for penetrating a corresponding penetration portion of the first object.

In the above movable handle fixing structure, the connecting portion has a fastening portion, the fastening portion is disposed on the base, and the fastening portion is used for fastening a pair of fasteners to the first object.

In the above movable handle fixing structure, the connecting portion has a fastening portion and a positioning column, the fastening portion is configured in the base, the fastening portion is disposed at one side of the positioning column and extends out of the base, the fastening portion fastens a pair of fasteners to the first object, and the positioning column penetrates the first object.

In the above movable handle fixing structure, the connecting portion has a stopping portion, and the stopping portion abuts against the first object.

In the above movable handle fixing structure, the connecting portion has an obstructing portion, and the obstructing portion resiliently abuts against the first object.

In the above movable handle fixing structure, the connecting portion has a fastening portion, wherein the fastening portion has a shaft body and a buckle body, the shaft body is configured on the base, and the buckle body is configured on the shaft body.

In the above movable handle fixing structure, the corresponding portion is a hole, a slot, a recess, a convex part, a step part, a flat part, an inclined part, an arc part or a curved part.

In the above movable handle fixing structure, the handle moves rotatably, laterally or longitudinally to drive the first positioning portion or the second positioning portion to move and be positioned at the corresponding portion.

In the above movable handle fixing structure, before moving to the corresponding portion, the first positioning portion or the second positioning portion of the handle passes through a guiding portion for guiding the first positioning portion or the second positioning portion to be positioned at the corresponding portion.

In the above movable handle fixing structure, the plates are resilient, such that the first positioning portion or the second positioning portion of the handle is positioned at a corresponding portion that is resiliently expanded and then buckled in the plates.

In the above movable handle fixing structure, the plates are resilient, such that before moving, the first positioning portion or the second positioning portion of the handle passes through a guiding portion for guiding the first positioning portion or the second positioning portion to be positioned at the corresponding portion that is resiliently expanded and then buckled into the plates.

In the above movable handle fixing structure, the receiving region is resilient for positioning the first positioning portion or the second positioning portion of the handle at the corresponding portion that is resiliently expanded and then buckled into the receiving region.

In the above movable handle fixing structure, the receiving region is resilient, such that before moving to the corresponding portion, the first positioning portion or the second positioning portion of the handle passes through a guiding portion for guiding the first positioning portion or the second positioning portion to be positioned at the corresponding portion that is resiliently expanded and then buckled into the receiving region.

In the above movable handle fixing structure, the guiding portion is an inclined surface, an arc-shaped surface, a curved surface, a step part, a flat surface, a recess or a convex part.

In the above movable handle fixing structure, the handle is movably assembled with the base through a shaft, such that the operating portion, the abutting portion and the fastening portion form a leverage structure.

In the above movable handle fixing structure, a carrier is formed, and the movable handle fixing structure is disposed on the carrier.

In the above movable handle fixing structure, after the movable handle fixing structure is taken up with a tool, the position of the movable handle fixing structure is compared with the position of the first object by a comparison device, and then the movable handle fixing structure is placed on the first object by the tool for assembly.

In the above movable handle fixing structure, the connecting portion has a has a welding part, and the welding part and a corresponding welding part of the first object have a weldable surface for heat welding the first object.

In the above movable handle fixing structure, the connecting portion has a has a welding part, and a solder layer is formed between the welding part and a weldable surface of a corresponding welding part of the first object for heat welding the first object.

In the above movable handle fixing structure, the tool is a vacuum suction tool, a clamp or a magnetic tool, and the comparison device is a visual comparison device, an image comparison device, a distance comparison device or an automatic comparison device.

In the above movable handle fixing structure, the corresponding welding part of the first object is a flat surface, a through hole, a through slot, a hole or a slot.

In the above movable handle fixing structure, the handle has at least one first positioning portion and at least one second positioning portion, and the handle is resilient, such that the first positioning portion or the second positioning portion of the handle is buckled into a corresponding portion after resilient deformation.

In the above movable handle fixing structure, the handle has at least one first positioning portion and at least one second positioning portion, and the handle is resilient, such that the first positioning portion or the second positioning portion of the handle passes through a guiding portion for guiding the first positioning portion or the second positioning portion to be buckled into a corresponding portion after resilient deformation.

In the above movable handle fixing structure, a resilient component is formed, one end of the resilient component abuts against the base, and the other end of the resilient component abuts against the handle.

In the above movable handle fixing structure, the operating portion is disposed on one end of the handle, the fastening portion is disposed on the other end of the handle, the abutting portion extends at a bottom of the other end of the handle, and the abutting portion corresponds to the fastening portion.

In the above movable handle fixing structure, a second object pushes the abutting portion to drive the fastening portion to be fastened to the second object, or the connecting portion drives the fastening portion and the abutting portion to move such that the second object is unfastened.

In the above movable handle fixing structure, the abutting portion pushes the second object to drive the fastening portion to unfasten the second object.

In the above movable handle fixing structure, the first object or the second object, which interacts with the handle, is a PCB board, a motherboard, a plastic board or a metal board.

Therefore, the present disclosure provides a movable handle fixing structure for fastening and unfastening at least two objects and achieving repeated and rapid fastening and unfastening.

### BRIEF DESCRIPTION OF THE DRAWINGS

FIG. 1 is a perspective schematic view showing the movable handle fixing structure according to the first preferred embodiment of the present disclosure.

FIG. 2 is an exploded schematic view showing the movable handle fixing structure according to the first preferred embodiment of the present disclosure.

FIG. 3 is a schematic side view showing the movable handle fixing structure according to the first preferred embodiment of the present disclosure.

FIG. 4 is a schematic view showing the movable handle fixing structure in use according to the first preferred embodiment of the present disclosure.

FIG. 5 is another schematic view showing the movable handle fixing structure according to the first preferred embodiment of the present disclosure.

FIG. 6 is a schematic view showing the movable handle fixing structure in use according to the second preferred embodiment of the present disclosure.

FIG. 7 is a schematic view showing the movable handle fixing structure in use according to the third preferred embodiment of the present disclosure.

FIG. 8 is a perspective schematic view showing the movable handle fixing structure according to the fourth preferred embodiment of the present disclosure.

FIG. 9 is a schematic side view showing the movable handle fixing structure according to the fourth preferred embodiment of the present disclosure.

FIG. 10 is a schematic bottom view showing the movable handle fixing structure according to the fourth preferred embodiment of the present disclosure.

FIG. 11 is a schematic view showing the movable handle fixing structure in use according to the fourth preferred embodiment of the present disclosure.

FIG. 12 is a schematic view showing the movable handle fixing structure in use according to the fifth preferred embodiment of the present disclosure.

FIG. 13 is another schematic view showing the movable handle fixing structure according to the first preferred embodiment of the present disclosure.

FIG. 14 is a schematic view showing the movable handle fixing structure according to the sixth preferred embodiment of the present disclosure.

FIG. 15 is a schematic view showing the movable handle fixing structure in use according to the seventh preferred embodiment of the present disclosure.

FIG. 16 is a schematic view showing the movable handle fixing structure in use according to the eighth preferred embodiment of the present disclosure.

### DETAILED DESCRIPTION OF THE INVENTION

To facilitate understanding of the object, characteristics and effects of this present disclosure, the following embodiments together with the accompanying drawings are provided for the detailed description of the present disclosure.

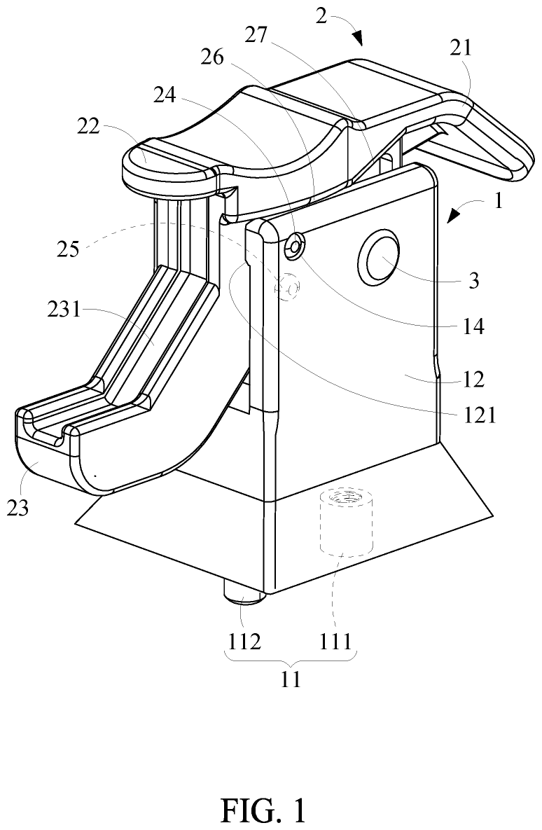

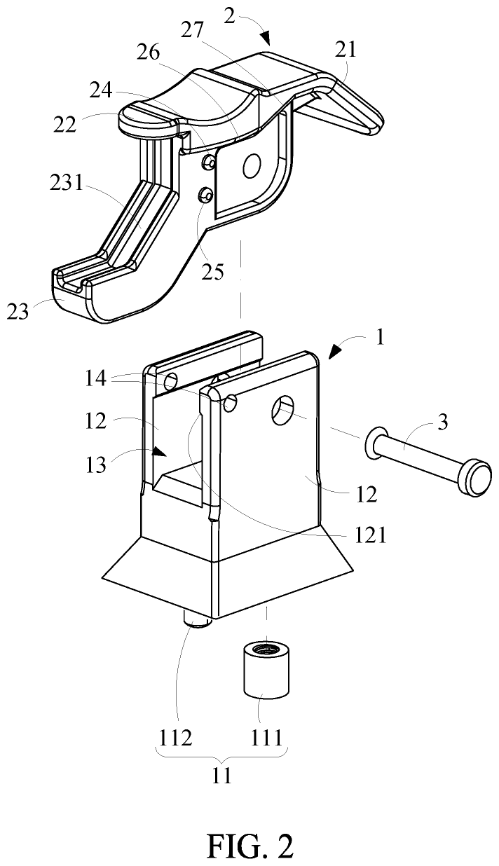

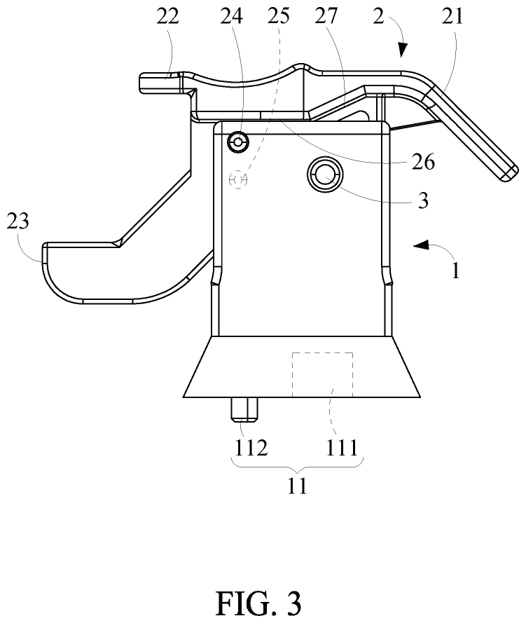

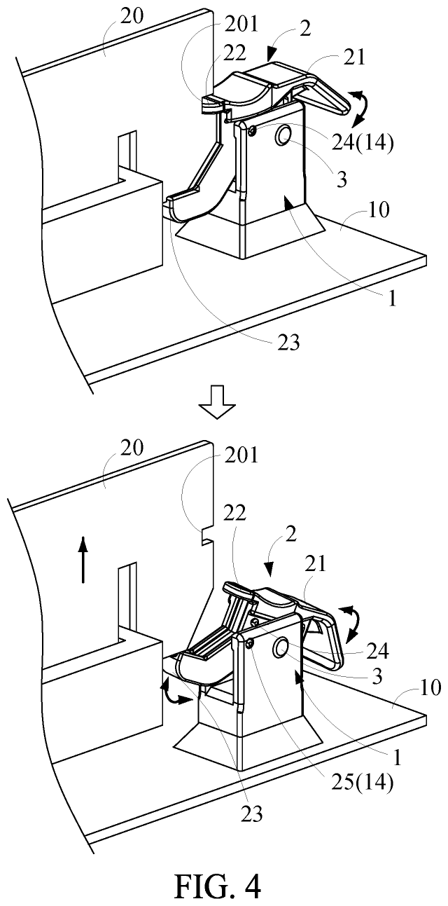

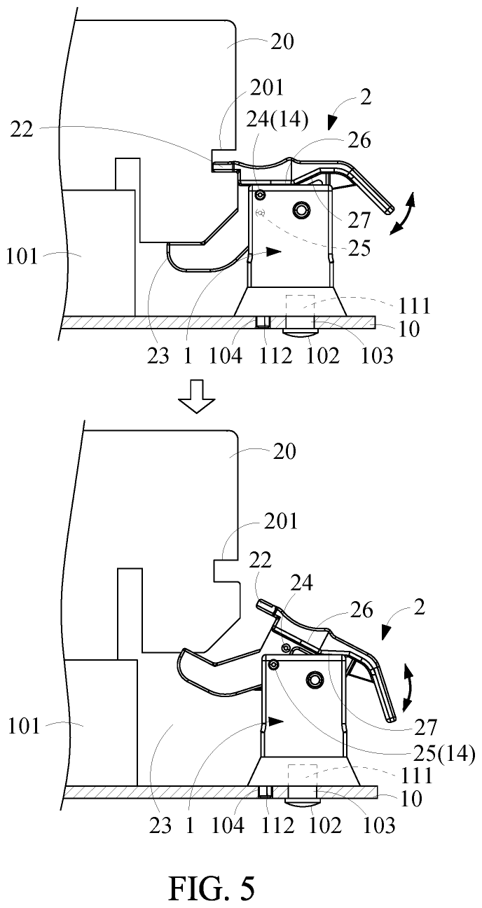

Please refer to FIG. 1 to FIG. 5. As shown in figures, the present disclosure provides a movable handle fixing structure, including a base 1 and a handle 2.

The base 1 includes a connecting portion 11, and the connecting portion 11 is used for being coupled with a first object 10.

The handle 2 is movably assembled with base 1, and has an operating portion 21, a fastening portion 22 and an abutting portion 23. The operating portion 21 is disposed at one end of the handle 2, the fastening portion 22 is disposed at the other end of the handle 2, the abutting portion 23 extends at a bottom of the other end of the handle 2, and the abutting portion 23 corresponds to the fastening portion 22.

When in use, the handle 2 may have only the operating portion 21 and the fastening portion 22, or only the operating portion 21 and the abutting portion 23, or only the fastening portion 22 and the abutting portion 23 (not shown in figures).

In the present disclosure, a second object 20 pushes the abutting portion 23 to drive the fastening portion 22 to be fastened to the second object 20, or the connecting portion 21 drives the fastening portion 22 and the abutting portion 23 to move such that the second object 20 is unfastened.

In one embodiment of the present disclosure, the first object 10 or the second object 20 can be a PCB board, a motherboard, a plastic board or a metal board.

In addition, the handle 2 of the present disclosure can have only an operating portion 21 and a fastening portion 22 and have no abutting portion 23, or can have only an operating portion 21 and an abutting portion 23 and have no fastening portion 22 (not shown in figures).

When in use, one or two movable handle fixing structures of the present disclosure can be used, the connecting portion 11 of the base 1 is coupled to the first object 10, then the second object 20 is connected to a connecting seat 101 on the first object, and at the same time a bottom of one side of the second object 20 pushes the abutting portion 23, such that the handle 2 moves rotatably on the base 1 to dive the fastening portion 22 to move toward one side of the second object 20, thereby fastening the fastening portion 22 to a fastening hole 201 of the second object. In addition, a downward external force can be applied to the operating portion 21 to drive the handle 2 to move rotatably in a reverse direction on the base 1, such that the operating portion 21 drives the fastening portion 22 and the abutting portion 23 to move, the abutting portion 23 pushes upward a bottom of one side of the second object 20, and at the same time the fastening portion 22 is kept away form the fastening hole 201 of the second object, thereby unfastening the second object 20. In this way, the movable handle fixing structure can be used for fastening and unfastening, so as to fasten and unfasten at least two objects and achieve repeated and rapid fastening and unfastening.

In one embodiment of the present disclosure, the handle 2 is movably assembled with the base 1 through a shaft 3, such that the operating portion 21, the abutting portion 23 and the fastening portion 22 form a leverage structure. In this way, the operating portion 21 utilizes the lever-saving effect during operation, such that the abutting portion 23 can easily abut against the second object 20. Therefore, the handle 2 is movably assembled with the base 1, such that the handle 2 is rotatably moved on the base 1 to drive the fastening portion 22 to move toward one side of the second object 20, and to drive the fastening portion 22 to be fastened to the fastening hole 201 of the second object 20; or the handle 2 drives the fastening portion 22 and the abutting portion 23 to move, such that the abutting portion 23 pushes upward the bottom of one side of the second object 20, and at the same time the fastening portion 22 is kept away from the fastening hole 201 of the second object 20, thereby unfastening the second object 20. In this way, the movable handle fixing structure can be used for fastening and unfastening, so as to fasten and unfasten at least two objects and achieve repeated and rapid fastening and unfastening.

In one embodiment of the present disclosure, the base 1 has two plate 12 which correspond to each other, the connecting portion 11 is disposed at the bottom of the plates 12, a receiving region 13 is form between the plates, the handle 2 is movably disposed in the receiving region 13, and the shaft 3 penetrates the plates, such that the handle 2 is movably assembled with the base 1. In this way, the handle 2 and the base 1 are movably assembled in the receiving region 13, such that the handle 2 is rotatably moved on the base 1 to drive the fastening portion 22 to move toward one side of the second object 20 and to drive the fastening portion 22 to be fastened to the fastening hole 201 of the second object 20; or the handle 2 drives the fastening portion 22 and the abutting portion 23 to move, such that the abutting portion 23 pushes upward the bottom of one side of the second object 20, and at the same time the fastening portion 22 is kept away from the fastening hole 201 of the second object 20, thereby unfastening the second object 20. In this way, the movable handle fixing structure can be used for fastening and unfastening, so as to fasten and unfasten at least two objects and achieve repeated and rapid fastening and unfastening.

In one embodiment of the present disclosure, the handle 2 includes at least one first positioning portion 24 and (or) at least one second positioning portion 25, the first positioning portion 24 and the second positioning portion 25 are disposed at different locations, the base 1 includes at least one corresponding portion 14, the corresponding portion 14 can be disposed on the plates 12 or one of the plates 12, and the first positioning portion 24 and the second positioning portion 25 can be respectively positioned on the corresponding portion 14, such that the handle 2 is rotatably moved to drive the first positioning portion 24 and (or) the second positioning portion 25 to move, so as to position the operating portion 21, the fastening portion 22 and the abutting portion 23. In this way, when the fastening portion 22 is driven to move to one side of the second object 20 such that the fastening portion 22 is fastened to the fastening hole 201 of the second object 20, the first positioning portion 24 is positioned on the corresponding portion 14 to fix the position of the handle 2 after the rotational movement, thereby achieving the firm fastening of the handle 2.

In addition, when the fastening portion 22 and the abutting portion 23 are driven to move such that the abutting portion 23 pushes upward the bottom of one side of the object 20 and at the same time the fastening portion 22 is kept away from the fastening hole 201 of the second object 20 so as to unfasten the second object 20, the second positioning portion 25 is positioned on the corresponding portion 14 to fix the position of the handle 2 after the rotational movement. Therefore, the positioning of the handle 2 after unfastening is achieved.

In one embodiment of the present disclosure, the corresponding portion 14 is a hole, a slot, a recess, a convex part, a step part, a flat part, an inclined part, an arc part or a curved part, such that the present disclosure can better meet the needs of actual applications.

In one embodiment of the present disclosure, the plates 12 are resilient and the resilience of the plates 12 makes the receiving region 13 resilient, such that the first positioning portion 24 or the second positioning portion 25 of the handle 2 is positioned at a corresponding portion 14 that is resiliently expanded and then buckled in the plates 12, so as to restrict the positions at which the operating portion 21, the fastening portion 22 and the abutting portion 23 stay. The position of the handle 2 after the rotational movement is fixed, such that the firm fastening of the handle 2 is achieved.

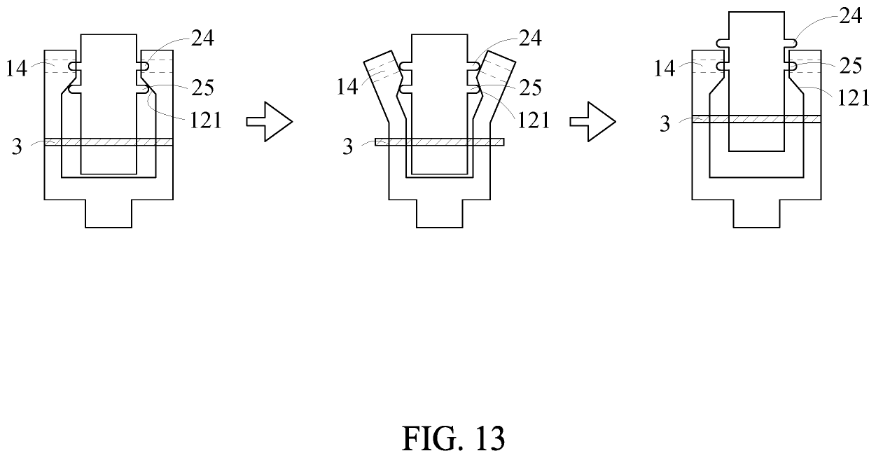

In one embodiment of the present disclosure, as shown in FIG. 13, the plates 12 are resilient, such that before moving to the corresponding portion 14, the first positioning portion 24 or the second positioning portion 25 of the handle 2 passes through a guiding portion 121 which guides the first positioning portion 24 or the second positioning portion 25 to be positioned at the corresponding portion 14 that is resiliently expanded and then buckled into the plates. In such way, the positions at which the operating portion 21, the fastening portion 22 and the abutting portion 23 stay are restricted, such that the firm fastening of the handle 2 is achieved.

The guiding portion 121 is an inclined surface, an arc-shaped surface, a curved surface, a step part, a flat surface, a recess or a convex part, such that the present disclosure can better meet the needs of actual applications.

In one embedment of the present disclosure, the handle 2 is resilient, such that the first positioning portion 24 or the second positioning portion 25 of the handle 2 passes through the guiding portion 121, which guides the first positioning portion 24 or the second positioning portion 25 to be buckled into the corresponding portion 14 after the resilient deformation, so as to restrict the positions at which the operating portion 21, the fastening portion 22 and the abutting portion 23 stay.

In one embodiment of the present disclosure, a first blocking portion 26 and (or) at least one second blocking portion 27 are formed at least one side of the handle 2, the first blocking portion 26 and the second blocking portion 27 are disposed at different positions, and the first blocking portion 26 and the second blocking portion 27 respectively block against a top surface of the base 1. In this way, when the fastening portion 22 is driven to move toward one side of the second object 20 such that the fastening portion 22 is fastened to the fastening hole 201 of the second object 20, the first positioning portion 24 is positioned on the corresponding portion 14, and at the same time the first abutting portion 26 abuts against the top surface of the base 1, so as to fix the position of the handle 2 after the rotational movement and to achieve the firm fastening of the handle 2.

In addition, when the fastening portion 22 and the abutting portion 23 are driven to move such that the abutting portion 23 pushes upward the bottom of one side of the object 20 and at the same time the fastening portion 22 is kept away from the fastening hole 201 of the second object 20 so as to unfasten the second object 20, the second positioning portion 25 is positioned on the corresponding portion 14 and at the same time the second blocking portion 27 blocks against the top surface of the base 1 so as to fix the position of the handle 2 after the rotational movement. Therefore, the positioning of the handle 2 after unfastening is achieved.

In one embodiment of the present disclosure, a positioning slot 231 is formed on a top surface of the abutting portion 23, the bottom of one side of the second object 20 can be positioned in the positioning slot 231, the positioning slot 231 is used as a moving track for the bottom of one side of the second object 20 to move in the positioning slot 231. In such way, when the bottom of one side of the second object 20 pushes the abutting portion 23, the bottom of one side of the second object 20 can be positioned in the positioning slot 231, so as to increase the stability of fastening or unfastening of the second object 20. In one embodiment of the present disclosure, the connecting portion 11 includes a fastening portion 111 and a positioning column 112, the fastening portion 111 is disposed in the base 1, the fastening portion 111 is disposed at one side of the positioning column 112 and extends out of the base 1, the fastening portion 111 fastens a pair of fasteners 102 to the first object 10, and the positioning column 112 penetrates the first object 10. Therefore, when the connecting portion 11 of the base 1 is coupled to the first object 10, the fastening portion 111 is corresponding to a through hole 103 of the first object 10, and the positioning column 112 correspondingly penetrates a corresponding penetration portion 104 of the first object 10. Then, the bottom of the first object 10 is fastened to the fastening portion 111 by the pair of fasteners 112, such that the base 1 is firmly coupled to the first object 10.

In one embodiment of the present disclosure, the base 1 is molded by injection and covers the fastening portion 111. In this way, the fastening portion 111 is firmly coupled to the base 1 so as to facilitate the subsequent coupling to the first object 10.

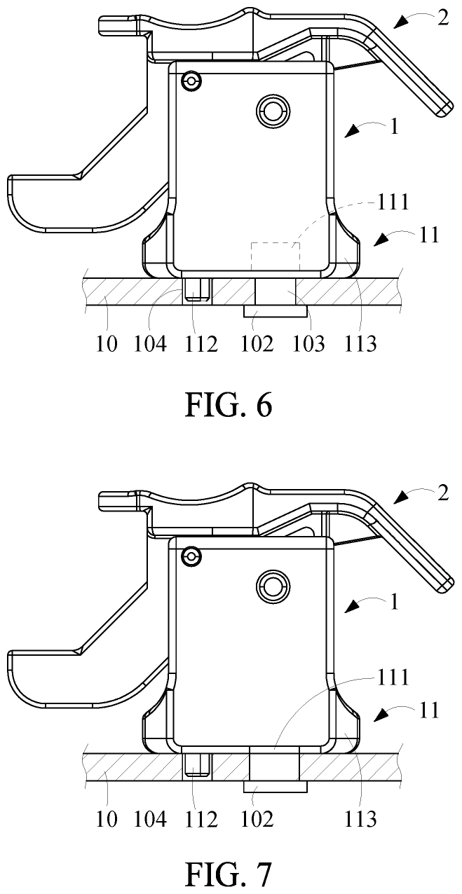

As shown in FIG. 6, this embodiment is different from the first embodiment in that the connecting portion 11 includes a fastening portion 111, a positioning column 112 and two stopping portions 113, the fastening portion 111 is disposed in the base 1, the fastening portion 111 is disposed at one side of the positioning column 112 and extends out of the base 1, the stopping portions 113 are disposed at two ends of the base 1, the fastening portion 111 is fastened to the first object 10 via a pair of fasteners 102, the positioning column 112 passes through the first object 10, and the stopping portions 113 abut against the first object 10. In this configuration, when the connecting portion 11 of the base 1 is coupled to the first object 10, the fastening portion 111 is corresponding to the through hole 103 of the first object 10, the positioning column 112 correspondingly penetrates a corresponding penetration portion 104 of the first object 10, and the stopping portions 13 abut against the surface of the first object 10. Then, the bottom of the first object 10 is fastened to the fastening portion 111 by the pair of fasteners 112, such that the base 1 is firmly coupled to the first object 10.

As shown in FIG. 7, this embodiment is different from the above embodiments in that the connecting portion 11 includes a fastening portion 111, a positioning column 112 and two stopping portions 113, the fastening portion 111 is disposed at one side of the positioning column 112, the fastening portion 111 and the positioning portion 112 extend out of the base 1, the spotting portions 113 are disposed at two ends of the base, the fastening portion 111 is fastened to the first object 10 by a pair of fasteners 102, the positioning column 112 penetrates the first object 10, and the stopping portions 113 abut against the first object 10. In this configuration, when the connecting portion 11 of the base 1 is coupled to the first object 10, the fastening portion 111 correspondingly penetrates a through hole 103 of the first object 10, and the positioning column 112 correspondingly penetrates a corresponding penetration portion 104 of the first object 10, such that the base 1 is positioned on the first object 10, and the stopping portions 113 abut against the surface of the first object 10. Then, the bottom of the first object 10 and the fastening portion 111 are fastened by the pair of fasteners 102, such that the base 1 is firmly coupled to the first object 10.

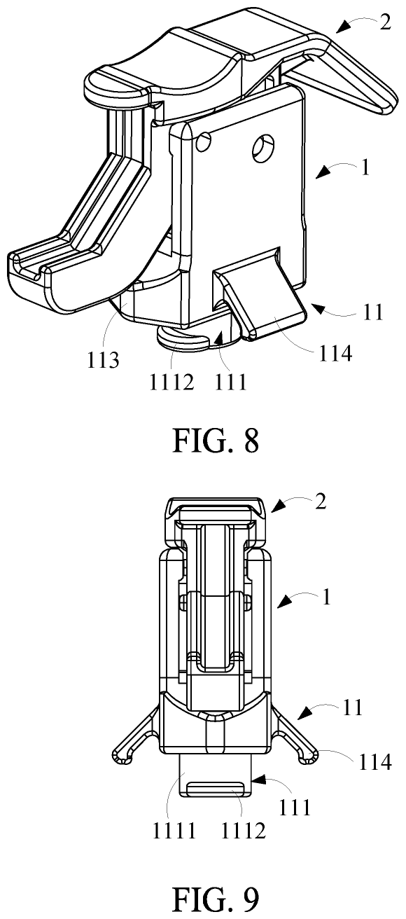

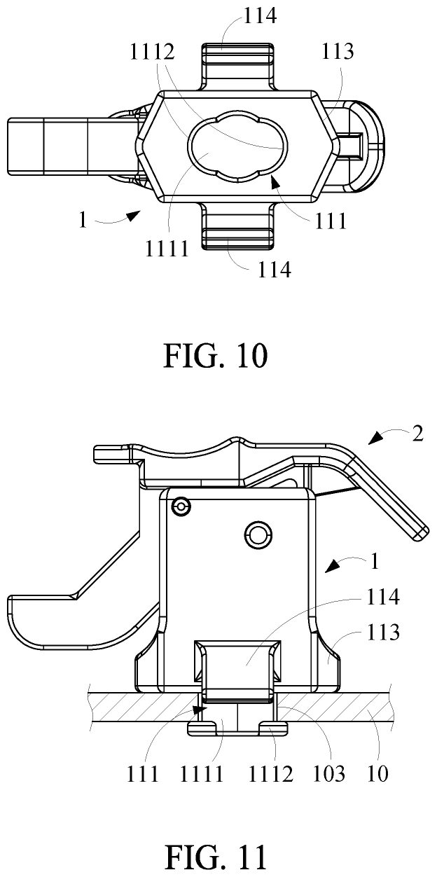

As shown in FIG. 8 to FIG. 11, this embodiment is different from the above embodiments in that the connecting portion 11 includes a fastening portion 111, two stopping portions 113 and two obstructing portions 114, the fastening portion 111 extends out of the base 1, the stopping portions 113 are disposed at two ends of the base 1, the obstructing portions 114 are disposed at two sides of the base 1, the fastening portion 111 is fastened to the first object 10, and the stopping portions 113 and the obstructing portions resiliently abut against the first object 10. The fastening portion 111 has a shaft body 1111 and two buckle bodies 1112, the shaft body 1111 is configured on the base 1, and the buckle bodies 1112 are configured on two sides of the shaft body 1111.

In this configuration, when the connecting portion 11 of the base 1 is connected to the first object 10, the fastening portion 111 correspondingly penetrates a through hole 103 of the first object 10, and the stopping portions 113 and the obstructing portions 114 abut against the surface of the first object 10. Then, the base 1 is rotated with the shaft body 1111 of the fastening portion 111 as an axis, such that the buckle bodies 1112 abut against the bottom of the first object 10, and the base 1 is firmly coupled to the first object 10.

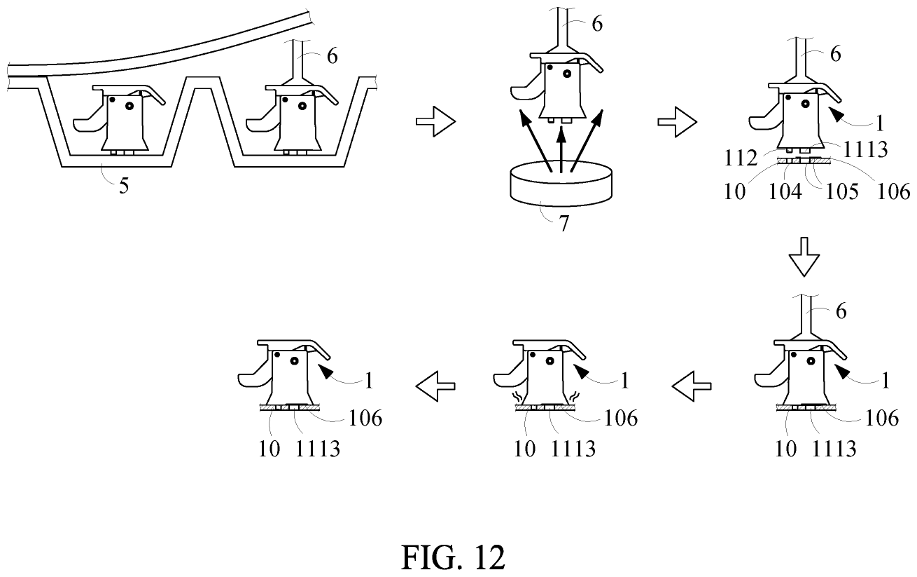

As shown in FIG. 12, this embodiment is different from the above embodiments in that a carrier 5 is included, wherein the movably handle fixing structure is placed on the carrier 5. After the movable handle fixing structure is taken up from the carrier 5 with a tool 6, the position of the movable handle fixing structure is compared with the position of the first object 10 by a comparison device 7, and then the movable handle fixing structure is placed on the first object 10 by the tool 6 for assembly, such that the accurate configuration is achieved.

In one embodiment of the present disclosure, the connecting portion 11 includes a welding part 1113, the welding part 1113 and a corresponding welding part 105 of the first object 10 have a weldable surface, a solder layer 106 is formed between the welding part 1113 and the weldable surface for heat welding the first object 10, such that the base 1 and the first object 10 are firmly assembled.

In one embodiment of the present disclosure, the tool 6 can be a vacuum suction tool, a clamp or a magnetic tool, and the comparison device is a visual comparison device, an image comparison device, a distance comparison device or an automatic comparison device, such that the present disclosure can better meet the needs of actual applications.

In one embodiment of the present disclosure, the corresponding welding part 105 of the first object 10 is a flat surface, a through hole, a through slot, a hole or a slot, such that the present disclosure can better meet the needs of actual applications.

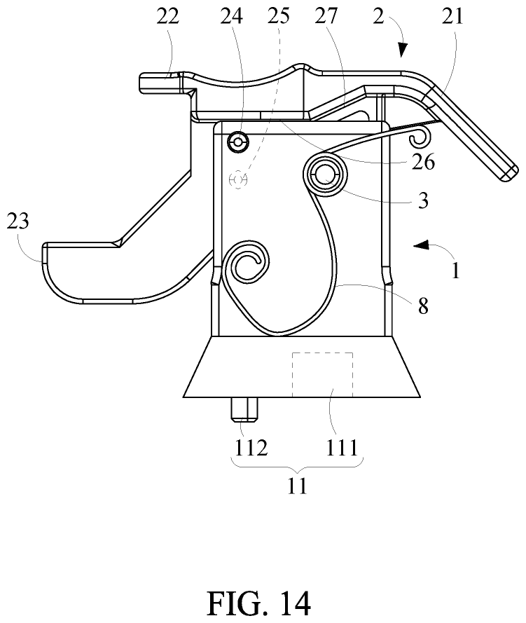

As shown in FIG. 14, this embodiment is different from the above embodiments in that a resilient component 8 is included, wherein one end of the resilient component 8 abuts against the base 1, and the other end of the resilient component 8 abuts against the handle 2. For example, the other end of the resilient component 8 can abut against the bottom or any other part of the handle 2. In this configuration, when the handle 2 is pressed with a force to rotatably move on the base 1, the resilient component 8 can be compressed; and when the handle 2 is no longer pressed, the resilient component 8 is restored, due to the resilience, so as to push the handle 2 back to the position, such that the fastening portion 22 is firmly fastened due to the resilience of the resilient component 8, and the better fastening is achieved.

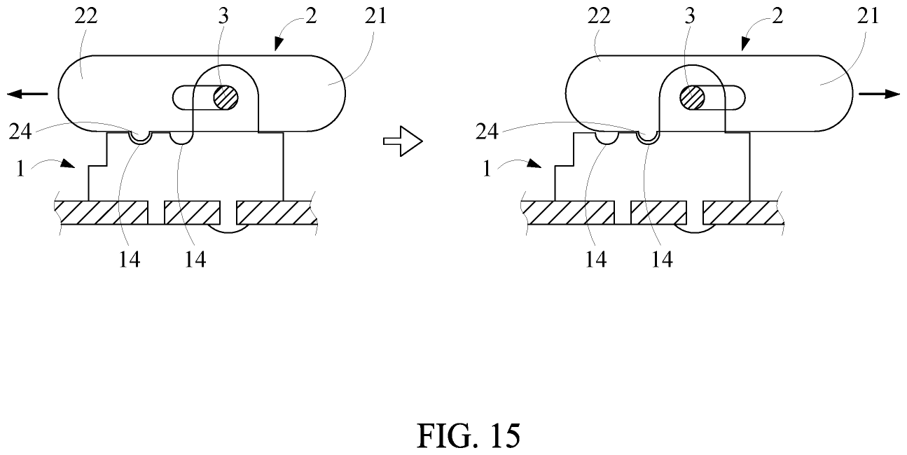

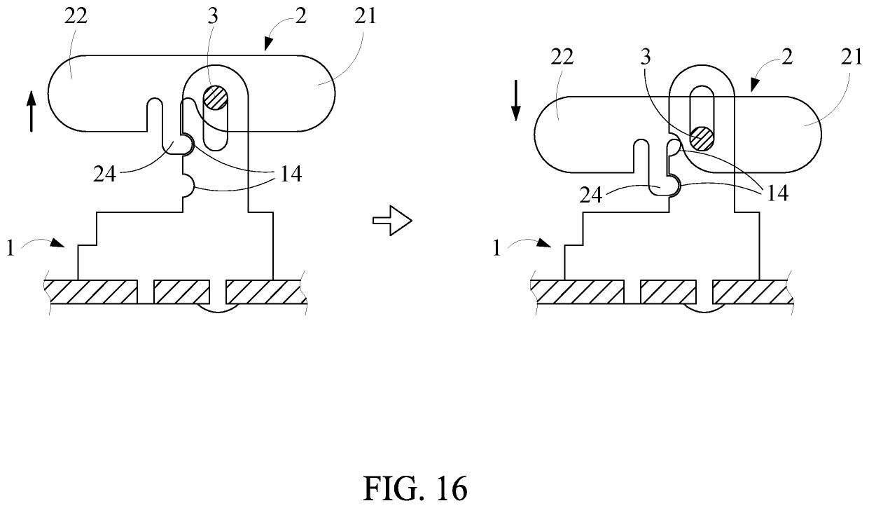

As shown in FIG. 15 and FIG. 16, this embodiment is different from the above embodiments in that the handle 2 can move on the base 1 laterally (as shown in FIG. 15) or longitudinally (as shown in FIG. 16), so as to drive the fastening portion 22 to move toward one side of the second object 20 and position the first positioning portion 24 on the corresponding portion 14, such that the fastening portion 22 is fastened to the second object (not shown in figures). In this configuration, the present disclosure provides a movable handle fixing structure for fastening and unfastening at least two objects and achieving repeated and rapid fastening and unfastening. Therefore, the present disclosure can better meet the needs of actual applications.

The present disclosure has been illustrated in the preferred embodiments above, but those skilled in the art should understand that the above-mentioned embodiments are only used to describe the present invention and should not be construed as limiting the scope of the present disclosure. It should be noted that all changes and substitutions equivalent to the above-mentioned embodiments should be included in the scope of the present disclosure. Therefore, the scope of the present disclosure should be defined by the claims of the patent application.

What is claimed is:

1. A movable handle fixing structure, comprising:
a base, having a connecting portion for being coupled with a first object; and
a handle, movably assembled with the base and having an operating portion and a fastening portion.

2. A movable handle fixing structure, comprising:
a base, having a connecting portion for being coupled with a first object; and
a handle, movably assembled with the base and having an operating portion and an abutting portion.

3. A movable handle fixing structure, comprising:
a base, having a connecting portion for being coupled with a first object; and
a handle, movably assembled with the base and having an abutting portion and a fastening portion.

4. The movable handle fixing structure of claim 1, wherein the handle is movably assembled with the base through a shaft, such that the operating portion, the abutting portion and the fastening portion form a leverage structure.

5. The movable handle fixing structure of claim 2, wherein the handle is movably assembled with the base through a shaft, such that the operating portion, the abutting portion and the fastening portion form a leverage structure.

6. The movable handle fixing structure of claim 3, wherein the handle is movably assembled with the base through a shaft, such that the operating portion, the abutting portion and the fastening portion form a leverage structure.

7. The movable handle fixing structure of claim 1, wherein the base is formed with a plurality of plates which are corresponding to each other, a first receiving region is formed among the plates, and the handle is movably disposed in the first receiving region; or the base has a second receiving region, and the handle is disposed in the second receiving region.

8. The movable handle fixing structure of claim 2, wherein the base is formed with a plurality of plates which are corresponding to each other, a first receiving region is formed among the plates, and the handle is movably disposed in the first receiving region; or the base has a second receiving region, and the handle is disposed in the second receiving region.

9. The movable handle fixing structure of claim 3, wherein the base is formed with a plurality of plates which are corresponding to each other, a first receiving region is formed among the plates, and the handle is movably disposed in the first receiving region; or the base has a second receiving region, and the handle is disposed in the second receiving region.

10. The movable handle fixing structure of claim 1, wherein the handle includes at least one of a first positioning portion and a second positioning portion, the first positioning portion and the second positioning portion are disposed at different positions, the base includes at least one corresponding portion, and the first positioning portion and the second positioning portion are respectively positioned at the corresponding portion.

11. The movable handle fixing structure of claim 2, wherein the handle includes at least one of a first positioning portion and a second positioning portion, the first positioning portion and the second positioning portion are disposed at different positions, the base includes at least one corresponding portion, and the first positioning portion and the second positioning portion are respectively positioned at the corresponding portion.

12. The movable handle fixing structure of claim 3, wherein the handle includes at least one of a first positioning portion and a second positioning portion, the first positioning portion and the second positioning portion are disposed at different positions, the base includes at least one corresponding portion, and the first positioning portion and the second positioning portion are respectively positioned at the corresponding portion.

13. The movable handle fixing structure of claim 1, further comprising at least one of a first blocking portion and a second blocking portion on at least one surface of the handle, wherein the first blocking portion and the second blocking portion are disposed at different positions, and the first blocking portion and the second blocking portion respectively block against a top surface of the base.

14. The movable handle fixing structure of claim 2, further comprising at least one of a first blocking portion and a second blocking portion on at least one surface of the handle, wherein the first blocking portion and the second blocking portion are disposed at different positions, and the first blocking portion and the second blocking portion respectively block against a top surface of the base.

15. The movable handle fixing structure of claim 3, further comprising at least one of a first blocking portion and a second blocking portion on at least one surface of the handle, wherein the first blocking portion and the second blocking portion are disposed at different positions, and the first blocking portion and the second blocking portion respectively block against a top surface of the base.

16. The movable handle fixing structure of claim 1, further comprising a positioning slot configured on a top surface of the abutting portion for positioning a second object therein, or the positioning slot used as a moving track for the second object to move therein.

17. The movable handle fixing structure of claim 2, further comprising a positioning slot configured on a top surface of the abutting portion for positioning a second object therein, or the positioning slot used as a moving track for the second object to move therein.

18. The movable handle fixing structure of claim 3, further comprising a positioning slot configured on a top surface of the abutting portion for positioning a second object therein, or the positioning slot used as a moving track for the second object to move therein.

19. The movable handle fixing structure of claim 7, wherein the plates are resilient, such that the first positioning portion or the second positioning portion of the handle is positioned at a corresponding portion that is resiliently expanded and then buckled in the plates; or the plates are resilient, such that before moving, the first positioning portion or the second positioning portion of the handle passes through a guiding portion which guides the first positioning portion or the second positioning portion to be positioned at the corresponding portion that is resiliently expanded and then buckled into the plates.

20. The movable handle fixing structure of claim 8, wherein the plates are resilient, such that the first positioning portion or the second positioning portion of the handle is positioned at a corresponding portion that is resiliently expanded and then buckled in the plates; or the plates are resilient, such that before moving, the first positioning portion or the second positioning portion of the handle passes through a guiding portion which guides the first positioning portion or the second positioning portion to be positioned at the corresponding portion that is resiliently expanded and then buckled into the plates.

21. The movable handle fixing structure of claim 9, wherein the plates are resilient, such that the first positioning portion or the second positioning portion of the handle is positioned at a corresponding portion that is resiliently expanded and then buckled in the plates; or the plates are resilient, such that before moving, the first positioning portion or the second positioning portion of the handle passes through a guiding portion which guides the first positioning portion or the second positioning portion to be positioned at the corresponding portion that is resiliently expanded and then buckled into the plates.

22. The movable handle fixing structure of claim 1, wherein the handle includes at lease one first positioning portion and at least one positioning portion, and the handle is resilient, such that the first positioning portion or the second positioning portion of the handle is buckled into a corresponding portion after resilient deformation, or the first positioning portion or the second positioning portion passes through a guiding portion which guides the first positioning portion or the second positioning portion to be buckled into the corresponding portion after the resilient deformation.

23. The movable handle fixing structure of claim 2, wherein the handle includes at least one first positioning portion and at least one positioning portion, and the handle is resilient, such that the first positioning portion or the second positioning portion of the handle is buckled into a corresponding portion after resilient deformation, or the first positioning portion or the second positioning portion passes through a guiding portion which guides the first positioning portion or the second positioning portion to be buckled into the corresponding portion after the resilient deformation.

24. The movable handle fixing structure of claim 3, wherein the handle includes at least one first positioning portion and at least one positioning portion, and the handle is resilient, such that the first positioning portion or the second positioning portion of the handle is buckled into a corresponding portion after resilient deformation, or the first positioning portion or the second positioning portion passes through a guiding portion which guides the first positioning portion or the second positioning portion to be buckled into the corresponding portion after the resilient deformation.

25. The movable handle fixing structure of claim 1, further comprising a resilient component, wherein one end of the resilient component abuts against the base, and the other end of the resilient component abuts against the handle.

26. The movable handle fixing structure of claim 2, further comprising a resilient component, wherein one end of the resilient component abuts against the base, and the other end of the resilient component abuts against the handle.

27. The movable handle fixing structure of claim 3, further comprising a resilient component, wherein one end of the resilient component abuts against the base, and the other end of the resilient component abuts against the handle.

28. The movable handle fixing structure of claim 1, wherein a second object pushes the abutting portion to drive the fastening portion to be fastened to the second object, or the connecting portion drives the fastening portion and the abutting portion to move such that the second object is unfastened, or the abutting portion pushes the second object to drive the fastening portion to unfasten the second object.

29. The movable handle fixing structure of claim 2, wherein a second object pushes the abutting portion to drive the fastening portion to be fastened to the second object, or the connecting portion drives the fastening portion and the abutting portion to move such that the second object is unfastened, or the abutting portion pushes the second object to drive the fastening portion to unfasten the second object.

30. The movable handle fixing structure of claim 3, wherein a second object pushes the abutting portion to drive the fastening portion to be fastened to the second object, or the connecting portion drives the fastening portion and the abutting portion to move such that the second object is unfastened, or the abutting portion pushes the second object to drive the fastening portion to unfasten the second object.
